(19) United States
(12) Patent Application Publication
(10) Pub. No.: US 2017/0104111 A1
(43) Pub. Date: Apr. 13, 2017

(54) SOLAR CELL STRUCTURE AND METHOD FOR MANUFACTURING THE SAME

(71) Applicant: Industrial Technology Research Institute, Hsinchu (TW)

(72) Inventors: Wei-Tse HSU, Taoyuan City (TW); Sheng-Wen CHAN, Taipei City (TW)

(73) Assignee: Industrial Technology Research Institute, Hsinchu (TW)

(21) Appl. No.: 15/281,415

(22) Filed: Sep. 30, 2016

Related U.S. Application Data
(63) Continuation-in-part of application No. 14/936,764, filed on Nov. 10, 2015, now abandoned.

(30) Foreign Application Priority Data
Oct. 7, 2015 (TW) 104132976

(51) Int. Cl. H01L 31/0224; H01L 31/032; H01L 31/18

(52) U.S. Cl. CPC H01L 31/022425; H01L 31/1884; H01L 31/18; H01L 31/0322

(57) ABSTRACT

A method of forming a solar cell structure is provided, which includes forming a metal electrode on a substrate, forming an absorber layer on the metal electrode, and forming a buffer layer on the absorber layer. The method also forms a titanium oxide layer on the buffer layer, wherein a thickness of the titanium oxide layer is greater than 0 and less than 10 nm. The method further forms a transparent conductive oxide layer on the titanium oxide layer. The step of forming the titanium oxide layer is atomic layer deposition (ALD) performed at a temperature of 100° C. to 180° C. with a precursor of titanium tetraisopropoxide.

### CROSS REFERENCE TO RELATED APPLICATIONS

This application is a Continuation-In-Part of pending U.S. patent application Ser. No. 14/936,764, filed on Nov. 10, 2015 and entitled “Solar cell structure and method for manufacturing the same”, which claims priority of Taiwan Patent Application No. 104132976, filed on Oct. 7, 2015, the entirety of which is incorporated by reference herein.

### BACKGROUND

Technical Field

The disclosure relates to a solar cell, and in particular it relates to a structure of the solar cell and a method of manufacturing the same.

Description of the Related Art

Global industries have greatly developed in recent years. Traditional power supplies have the advantage of low cost, but they also have potential problems such as causing radiation and environmental pollution. Many research departments are focusing on green alternative energy, and solar cells are very promising. Traditional solar cells were mainly based on silicon wafers, but thin-film solar cells have been developed in recent years. However, the copper indium gallium selenide (CIGS) series of solar cells are the best choice for non-toxicity, high efficiency, and high stability.

CIGS is a chalcopyrite compound with a tetragonal crystal structure. The CIGS can be applied in solar cells due to a high optical absorption coefficient, wide light-absorption band, stable chemical properties, and direct bandgap. A general CIGS solar cell includes an electrode layer, a CIGS layer, a CdS layer, an i-ZnO layer, an AZO layer, and an optional finger electrode layer sequentially formed on a substrate. The i-ZnO layer (on the CdS layer) may ameliorate the problem of incomplete coverage of the buffer layer, and efficiently inhibit leakage current of the solar cell. In addition, the problem of the CdS layer being damaged by ion bombardment during sputtering of the AZO layer can be reduced by the i-ZnO layer. However, the i-ZnO layer with a thickness of 50 nm to 100 nm, thereby absorbing the incident light to reduce efficiency of the solar cell. Moreover, the current collection is obstructed by the i-ZnO layer with high resistance.

Accordingly, a novel CIGS cell structure for overcoming the issue from the conventional i-ZnO layer is called for.

### BRIEF SUMMARY

One embodiment of the disclosure provides a solar cell structure, comprising a substrate; a metal electrode on the substrate; an absorber layer on the metal electrode; a buffer layer on the absorber layer; a titanium oxide layer on the buffer layer, wherein the titanium oxide layer has a thickness of greater than 0 and less than 10 nm; and a transparent conductive oxide layer on the titanium oxide layer.

One embodiment of the disclosure provides a method of manufacturing a solar cell structure, comprising forming a metal electrode on a substrate; forming an absorber layer on the metal electrode; forming a buffer layer on the absorber layer; forming a titanium oxide layer on the buffer layer, wherein the titanium oxide layer has a thickness of greater than 0 and less than 10 nm; and forming a transparent conductive oxide layer on the titanium oxide layer, wherein the step of forming a titanium oxide layer on the buffer layer is an atomic layer deposition performed at a temperature of 100° C. to 180° C. with a precursor of titanium tetraisopropoxide.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows a solar cell in one embodiment of the disclosure.

### DETAILED DESCRIPTION

The following description is of the best-contemplated mode of carrying out the disclosure. This description is made for the purpose of illustrating the general principles of the disclosure and should not be taken in a limiting sense. The scope of the disclosure is best determined by reference to the appended claims.

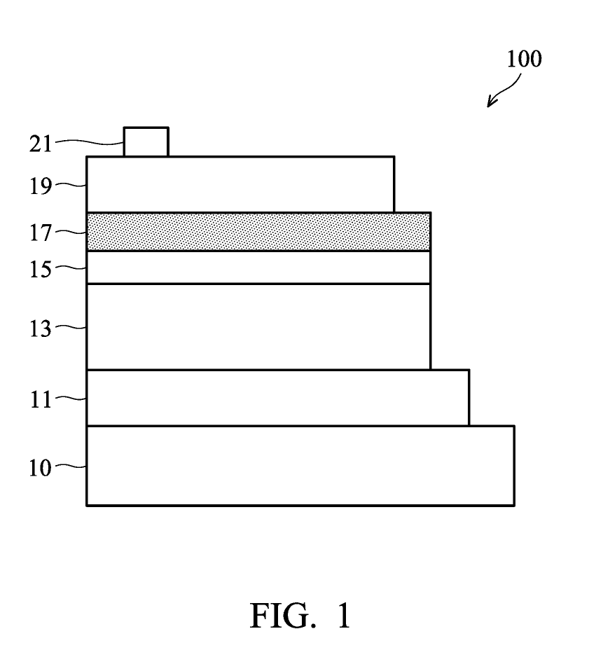

FIG. 1 shows a solar cell 100 in one embodiment of the disclosure. A substrate 10 such as plastic, stainless steel, glass, quartz, or other general substrate material is provided. A metal electrode 11 is then formed on the substrate 10, and the method of forming the metal electrode 11 can be sputtering, physical vapor deposition, spray coating, or the like. In one embodiment, the metal electrode 11 can be chromium, molybdenum, copper, silver, gold, platinum, other metal, or an alloy thereof. An absorber layer 13 is then formed on the metal electrode 11. In one embodiment, the absorber layer 13 can be copper indium gallium selenide (CIGS), copper indium gallium selenide sulfide (CIGSS), copper gallium selenide (CGS), copper gallium selenide sulfide (CGSS), or copper indium selenide (CIS). The absorber layer 13 can be formed by evaporation, sputtering, plating, nanoparticle coating, and the like. See Solar Energy, 77 (2004) page 749-756 and Thin Solid Films, 480-481 (2005) page 99-109.

A buffer layer 15 is then formed on the absorber layer 13. In one embodiment, the buffer layer 15 can be cadmium sulfide, zinc sulfide, tin zinc oxide, zinc oxide, zinc magnesium oxide, or indium sulfide. In one embodiment, the buffer layer 15 has a thickness of greater than 0 and less than or equal to 30 nm. If the solar cell 100 is free of the buffer layer 15 (e.g. the subsequently formed titanium oxide layer 17 directly contacts the absorber layer 13), the maximum efficiency of the solar cell 10 cannot be immediately achieved and needs a period of time such as 10 minutes to 1 hour under sunlight. A solar cell with an overly thick buffer layer 15 may reduce the amount of light travelling through the buffer layer 15 and largely increase the series-resistance, thereby lowering the solar cell efficiency. Solar Energy, 77 (2004), page 749-756 can be referred to the method of forming the buffer layer 15. It may utilize chemicals such as cadmium sulfate (or indium sulfate), thiocarbamide, and ammonia at an operation temperature of 50° C. to 75° C.

A titanium oxide layer 17 is then formed on the buffer layer 15 by ALD at a temperature of 100° C. to 180° C. with a precursor of titanium tetraisopropoxide. An overly high ALD temperature may damage the absorber layer 13. An overly low ALD temperature not only largely decreases the film formation rate, but also largely degrade the film quality due to be unable to remove carbon of the precursor. In one embodiment, the titanium oxide layer 17 is amorphous. It should be noted that the ALD precursor should be free of halogen (e.g. TiCl₄, TiBr₄, or the like), thereby preventing the underlying buffer layer 15 (or even the absorber layer 13) from being damaged by halogen produced during the ALD. In one embodiment, the titanium oxide layer 17 has a thickness of greater than 0 and less than 10 nm. An overly thick titanium oxide layer 17 will reduce the amount of light travelling through the titanium oxide layer 17, thereby lowering the solar cell efficiency. If the solar cell is free of the titanium oxide layer 17 (e.g. the subsequently formed transparent conductive oxide layer 19 directly contacts the buffer layer 15), the leakage current of the solar cell cannot be efficiently inhibited, and the problem of the buffer layer 15 being damaged by ion bombardment during sputtering of the transparent conductive oxide layer 19 cannot be avoided. On the other hand, the titanium oxide layer thickness is related to the composition of the absorber layer 13. For example, when the absorber layer 13 is CIGS, the titanium oxide layer 17 may have a thickness of greater than 0 and less than 10 nm.

A transparent conductive oxide layer 19 is then formed on the titanium oxide layer 17. In one embodiment, the transparent conductive oxide layer 19 can be indium tin oxide (no), indium zinc oxide (IZO), aluminum zinc oxide (AZO), gallium zinc oxide (GZO), aluminum gallium zinc oxide (AGZO), cadmium tin oxide, zinc oxide, zirconium oxide, or other transparent conductive oxide material. The transparent conductive oxide layer 19 can be formed by sputtering, evaporation, ALD, pyrolysis, nanoparticles coating, and the like.

In one embodiment, a finger electrode 21 can optionally be formed on the transparent conductive oxide layer 19. The finger electrode 21 can be Ni—Al alloy, and the method of forming the finger electrode 21 can include sputtering, lithography, etching, and/or other suitable processes. In one embodiment, when the transparent conductive oxide layer 19 has a small surface area, the finger electrode 21 can be omitted.

Compared to the conventional i-ZnO layer disposed between the buffer layer and the transparent conductive oxide layer, the titanium oxide layer 17 has a lower resistance and a higher amount of incident light, such that the solar cell with the titanium oxide layer 17 has a higher photoelectric conversion efficiency.

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

### EXAMPLES

### Example 1 (A Titanium Oxide Layer was Disposed Between a Buffer Layer and a Transparent Conductive Oxide Layer)

A Cr layer and a Mo layer with a thickness of 1000 nm were respectively formed on a stainless substrate by sputtering to serve as a metal electrode. Thereafter, a precursor of CuInGa oxide nanoparticles was coated on the Mo layer, and then chemically reduced, selenized, and sulfurized to prepare a CIGSeS absorber layer with a thickness of about 3000 nm. 5 wt % of KCN aqueous solution was then used to clean the CIGSeS absorber layer to remove the copper selenide compound thereof for completing an absorber layer. A CdS film with a thickness of 50 nm was formed on the absorber layer by chemical bath deposition (CBD) to serve as a buffer layer, wherein the CBD temperature was controlled at 65° C. A titanium oxide layer with a thickness of 3 nm was then formed on the buffer layer by atomic layer deposition (ALD), wherein the ALD temperature was controlled at 120° C., and the ALD cursor was titanium tetraisopropoxide. An AZO layer with a thickness of 300 nm was then formed on the titanium oxide layer to serve as a transparent conductive oxide layer. A Ni—Al finger electrode was then formed on the transparent conductive oxide layer, thereby completing a solar cell structure.

### Example 2-1, 2-2

Examples 2-1 and 2-2 were similar to Example 1, and the difference in Examples 2-1 and 2-2 was the thickness of the titanium oxide layer being increased to 5 nm.

### Example 3

Example 3 was similar to Example 1, and the difference in Example 3 was the thickness of the titanium oxide layer being increased to 7 nm.

### Example 4

Example 4 was similar to Example 1, and the difference in Example 4 was the thickness of the titanium oxide layer being increased to 9 nm.

### Example 5

Example 5 was similar to Example 1, and the difference in Example 2 was the thickness of the titanium oxide layer being increased to 10 nm.

### Example 6

Example 6 was similar to Example 1, and the difference in Example 3 was the thickness of the titanium oxide layer being increased to 15 nm.

### Example 7

Example 7 was similar to Example 1, and the difference in Example 4 was the thickness of the titanium oxide layer being increased to 30 nm.

### Comparative Examples 1 to 7 (An i-ZnO Layer was Disposed Between a Buffer Layer and a Transparent Conductive Oxide Layer)

A Cr layer and a Mo layer with a thickness of 1000 nm were respectively formed on a stainless substrate by sputtering to serve as a metal electrode. Thereafter, a precursor of CuInGa oxide nanoparticles was coated on the Mo layer, and then chemically reduced, selenized, and sulfurized to prepare a CIGSeS absorber layer with a thickness of about 3000 nm. 5 wt % of KCN aqueous solution was then used to clean the CIGSeS absorber layer to remove the copper selenide compound thereof for completing an absorber layer. A CdS film with a thickness of 50 nm was formed on the absorber layer by chemical bath deposition (CBD) to serve as a buffer layer, wherein the CBD temperature was controlled to 65° C. An i-ZnO layer with a thickness of 50 nm was then formed on the buffer layer by sputtering. An AZO layer with a thickness of 300 nm was then formed on the i-ZnO layer to serve as a transparent conductive oxide layer. A Ni—Al finger electrode was then formed on the transparent conductive oxide layer, thereby completing a solar cell structure.

Comparative Examples 1 to 7 and Examples 1 to 7 had the same structure before forming the i-ZnO layer/titanium oxide layer. In experiments, the semi-product of the solar cell (after forming the buffer layer) can be divided to two semi-products with the same area. The i-ZnO layer/the AZO layer/the Ni—Al finger electrode (Comparative Example 1 to 7) and the titanium oxide layer/the AZO layer/the Ni—Al finger electrode (Examples 1 to 7) were respectively formed on the different semi-products.

As shown in Tables 1 to 8, the electrical properties influenced by the titanium oxide thicknesses can be compared between cell-1, cell-2, cell-3, cell-4, cell-5, cell-6, cell-7, and cell-8. When the thickness of the titanium oxide layer was increased from 5 nm to 30 nm, the V_{oc} of the solar cell decreased from 0.564V to 0.541V. The reason for the phenomenon described above may be an overly long ALD period diffusing Cd ions too much, such that the V_{oc} of the solar cell was reduced. In addition, the J_{sc} of the solar cells in Examples were also slightly reduced by increasing the titanium oxide layer thickness. The F.F. of the solar cells in the Examples were obviously reduced by increasing the titanium oxide layer thickness due to lowering Rₛₕ and increasing Rₛ. Accordingly, the thicker titanium oxide layer made the solar cell have an obvious lower efficiency, e.g. the efficiency was decreased from 12.96% to 11.36% when the titanium oxide layer thickness was increased from 5 nm to 30 nm. When the titanium oxide layer thickness was further reduced to 3 nm, e.g. Example 1 and Example 2-1, the efficiency of cell-1 was slightly less than that of cell-2.

As shown in Tables 4, cell-4 included two solar cells of different structures in Comparative Example 3 and Example 3. The electrical properties of the cell-4 illustrate that the open-circuit voltage (V_{oc}) of the two solar cell structures in Example 3 and the Comparative Example 3 are substantially the same without any obvious difference. Comparing the short-circuit current (J_{sc}) of the solar cells, the J_{sc} of the solar cell in Example 3 is 0.62 mA/cm² (2%) higher than that of the Comparative Example 3. The higher J_{sc} should be a result of the higher light transmittance of the titanium oxide layer. Comparing the filling factor (FF) of the solar cells in Example 3 and the Comparative Example 3, they are substantially the same without any obvious difference due to the series-resistance (Rₛ) and the shunt-resistance (Rₛₕ) of the solar cells in Example 3 and the Comparative Example 3 being substantially the same without any obvious difference. Comparing the efficiency of the solar cells, the efficiency of the solar cell in Example 3 is 0.25% higher than that of the Comparative Example 3, and the higher efficiency mainly comes from the higher J_{sc}. See Table 4.

Note that the efficiency comparison will be more appropriate to consider the Comparative Example and Example to avoid the experiment error. For example, the efficiency enhancement of Example 1 versus Comparative Example 1 in Table 1 should be (12.85−12.66)/12.66=+1.5%, the efficiency enhancement of Example 2-1 versus Comparative Example 2 in Table 2 should be (12.96−12.68)/12.68=+2.2%, the efficiency enhancement of Example 2-2 versus Comparative Example 2 in Table 3 should be (12.62−12.26)/12.26=+2.9%, the efficiency enhancement of Example 3 versus Comparative Example 3 in Table 4 should be (12.78−12.53)/12.53=+2.0%, the efficiency enhancement of Example 4 versus Comparative Example 4 in Table 5 should be (12.86−12.65)/12.65=+1.6%, the efficiency enhancement of Example 5 versus Comparative Example 5 in Table 6 should be (12.72−12.56)/12.56=+1.2%, the efficiency enhancement of Example 6 versus Comparative Example 6 in Table 7 should be (12.12−12.65)/12.65=−4.2%, and the efficiency enhancement of Example 7 versus Comparative Example 7 in Table 8 should be (11.36−12.51)/12.51=−9.2%. Accordingly, the cells with a titanium oxide layer thickness less than 10 nm had higher efficiency enhancements (e.g. ≧+1.5%) than the cells with a titanium oxide layer thickness greater than or equal to 10 nm.

TABLE 1
(TiO₂ = 3 nm in Example 1)

| | | J_{SC} | FF | Efficiency | | |
|---|---|---|---|---|---|---|
| Cell-1 | V_{oc} (V) | (mA/cm²) | (%) | (%) | Rₛₕ (Ω) | Rₛ (Ω) |
| Example 1 | 0.562 | 32.33 | 70.63 | 12.85 | 5748 | 20.9 |
| Comparative | 0.564 | 31.39 | 71.42 | 12.66 | 5825 | 20.3 |
| Example 1 | | | | | | |

TABLE 2
(TiO₂ = 5 nm in Example 2-1)

| | | J_{SC} | FF | Efficiency | | |
|---|---|---|---|---|---|---|
| Cell-2 | V_{oc} (V) | (mA/cm²) | (%) | (%) | Rₛₕ (Ω) | Rₛ (Ω) |
| Example 2-1 | 0.564 | 32.25 | 71.33 | 12.96 | 5748 | 20.0 |
| Comparative | 0.565 | 31.53 | 71.27 | 12.68 | 6697 | 20.2 |
| Example 2-1 | | | | | | |

TABLE 3
(TiO₂ = 5 nm in Example 2-2)

| | | J_{SC} | FF | Efficiency | | |
|---|---|---|---|---|---|---|
| Cell-3 | V_{oc} (V) | (mA/cm²) | (%) | (%) | Rₛₕ (Ω) | Rₛ (Ω) |
| Example 2-2 | 0.563 | 31.66 | 70.82 | 12.62 | 6583 | 21.5 |
| Comparative | 0.563 | 31.00 | 70.30 | 12.26 | 5157 | 21.3 |
| Example 2-2 | | | | | | |

TABLE 4
(TiO₂ = 7 nm in Example 3)

| | | J_{SC} | FF | Efficiency | | |
|---|---|---|---|---|---|---|
| Cell-4 | V_{oc} (V) | (mA/cm²) | (%) | (%) | Rₛₕ (Ω) | Rₛ (Ω) |
| Example 3 | 0.564 | 31.86 | 71.13 | 12.78 | 5889 | 20.4 |
| Comparative | 0.564 | 31.24 | 71.11 | 12.53 | 5925 | 20.5 |
| Example 3 | | | | | | |

TABLE 5
(TiO₂ = 9 nm in Example 4)

| | | J_{SC} | FF | Efficiency | | |
|---|---|---|---|---|---|---|
| Cell-5 | V_{oc} (V) | (mA/cm²) | (%) | (%) | Rₛₕ (Ω) | Rₛ (Ω) |
| Example 4 | 0.565 | 31.89 | 71.41 | 12.86 | 6174 | 20.4 |
| Comparative | 0.565 | 31.35 | 71.42 | 12.65 | 6332 | 20.6 |
| Example 4 | | | | | | |

TABLE 6
(TiO₂ = 10 nm in Example 5)

| | | J_{SC} | FF | Efficiency | | |
|---|---|---|---|---|---|---|
| Cell-6 | V_{oc} (V) | (mA/cm²) | (%) | (%) | Rₛₕ (Ω) | Rₛ (Ω) |
| Example 5 | 0.565 | 31.74 | 71.01 | 12.72 | 5076 | 20.8 |
| Comparative | 0.564 | 31.21 | 71.36 | 12.56 | 6183 | 20.5 |
| Example 5 | | | | | | |

TABLE 7
(TiO₂ = 15 nm in Example 6)

| | | J_{SC} | FF | Efficiency | | |
|---|---|---|---|---|---|---|
| Cell-7 | V_{oc} (V) | (mA/cm²) | (%) | (%) | Rₛₕ (Ω) | Rₛ (Ω) |
| Example 6 | 0.549 | 31.54 | 70.01 | 12.12 | 4993 | 22.5 |
| Comparative | 0.564 | 31.21 | 71.86 | 12.65 | 6230 | 20.2 |
| Example 6 | | | | | | |

TABLE 8
(TiO₂ = 30 nm in Example 7)

| | | J_{SC} | FF | Efficiency | | |
|---|---|---|---|---|---|---|
| Cell-8 | V_{oc} (V) | (mA/cm²) | (%) | (%) | Rₛₕ (Ω) | Rₛ (Ω) |
| Example 7 | 0.541 | 31.48 | 66.70 | 11.36 | 3789 | 27.4 |
| Comparative | 0.565 | 31.15 | 71.12 | 12.51 | 5576 | 20.7 |
| Example 7 | | | | | | |

### Example 8

Example 8 was similar to Example 4, and the difference in Example 8 was the thickness of the CdS buffer layer being reduced to 10 nm. Cell-9 of Example 8 was formed by a method similar to that for cell-5 (of Example 4), but cell-9 was free of Comparative Example

### Example 9

Example 9 was similar to Example 4, and the difference in Example 8 was the thickness of the CdS buffer layer being reduced to 30 nm. Cell-10 of Example 9 was formed by a method similar to that for cell-5 (of Example 4), but cell-10 was free of Comparative Example

TABLE 9

| | V_{oc} | J_{SC} | FF | Efficiency | | |
|---|---|---|---|---|---|---|
| | (V) | (mA/cm²) | (%) | (%) | Rₛₕ (Ω) | Rₛ (Ω) |
| 9 nm-TiO₂- | 0.564 | 32.24 | 71.26 | 12.96 | 5007 | 20.5 |
| 10 nm-CdS- | | | | | | |
| CIGS | | | | | | |
| (Example 8) | | | | | | |
| 9 nm-TiO₂- | 0.564 | 32.01 | 71.53 | 12.91 | 5624 | 20.4 |
| 30 nm-CdS- | | | | | | |
| CIGS | | | | | | |
| (Example 9) | | | | | | |
| 9 nm-TiO₂- | 0.565 | 31.89 | 71.41 | 12.86 | 6174 | 20.4 |
| 50 nm-CdS- | | | | | | |
| CIGS | | | | | | |
| (Example 4) | | | | | | |
| i-ZnO-50 nm- | 0.565 | 31.35 | 71.42 | 12.65 | 6332 | 20.6 |
| CdS-CIGS | | | | | | |
| (Comparative | | | | | | |
| Example 4) | | | | | | |

As shown in Table 9, the TiO₂ layer with a thickness of less than 10 nm may further reduce thickness of the CdS buffer layer (e.g. 30 nm, 10 nm) to improve the efficiency of the cell.

While the disclosure has been described by way of example and in terms of the preferred embodiments, it is to be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solar cell structure, comprising:
a substrate;
a metal electrode on the substrate;
an absorber layer on the metal electrode;
a buffer layer on the absorber layer;
a titanium oxide layer on the buffer layer, wherein the titanium oxide layer has a thickness of greater than 0 and less than 10 nm; and
a transparent conductive oxide layer on the titanium oxide layer.

2. The solar cell structure as claimed in claim 1, wherein the buffer layer has a thickness of greater than 0 and less than or equal to 30 nm.

3. The solar cell structure as claimed in claim 1, wherein the metal electrode comprises chromium, molybdenum, copper, silver, gold, platinum, or an alloy thereof.

4. The solar cell structure as claimed in claim 1, wherein the absorber layer comprises copper indium gallium selenide, copper indium gallium selenide sulfide, copper gallium selenide, copper gallium selenide sulfide, or copper indium selenide.

5. The solar cell structure as claimed in claim 1, wherein the buffer layer comprises cadmium sulfide, zinc sulfide, tin zinc oxide, zinc oxide, zinc magnesium oxide, or indium sulfide.

6. The solar cell structure as claimed in claim 1, wherein the transparent conductive oxide layer comprises indium tin oxide, indium zinc oxide, aluminum zinc oxide, gallium zinc oxide, aluminum gallium zinc oxide, cadmium tin oxide, zinc oxide, or zirconium oxide.

7. The solar cell structure as claimed in claim 1, wherein the titanium oxide layer is amorphous.

8. A method of manufacturing a solar cell structure, comprising:
forming a metal electrode on a substrate;
forming an absorber layer on the metal electrode;
forming a buffer layer on the absorber layer;
forming a titanium oxide layer on the buffer layer, wherein the titanium oxide layer has a thickness of greater than 0 and less than 10 nm; and
forming a transparent conductive oxide layer on the titanium oxide layer,
wherein the step of forming a titanium oxide layer on the buffer layer is an atomic layer deposition performed at a temperature of 100° C. to 180° C. with a precursor of titanium tetraisopropoxide.

9. The method as claimed in claim 8, wherein the buffer layer has a thickness of greater than 0 and less than or equal to 30 nm.

10. The method as claimed in claim 8, wherein the absorber layer comprises copper indium gallium selenide, copper indium gallium selenide sulfide, copper gallium selenide, copper gallium selenide sulfide, or copper indium selenide.

11. The method as claimed in claim 8, wherein the buffer layer comprises cadmium sulfide, zinc sulfide, tin zinc oxide, zinc oxide, zinc magnesium oxide, or indium sulfide.

12. The method as claimed in claim 8, wherein the titanium oxide layer is amorphous.
